(19) United States
(12) Patent Application Publication
(10) Pub. No.: US 2014/0137961 A1
(43) Pub. Date: May 22, 2014

(54) MODULAR CHEMICAL DELIVERY SYSTEM

(71) Applicant: APPLIED MATERIALS, INC., Santa Clara, CA (US)

(72) Inventors: CHIEN-TEH KAO, Sunnyvale, CA (US); MEI CHANG, Saratoga, CA (US); HYMAN W. H. LAM, San Jose, CA (US); YU CHANG, San Jose, CA (US); JOEL M. HUSTON, San Jose, CA (US); OLKAN CUVALCI, Sunnyvale, CA (US)

(73) Assignee: APPLIED MATERIALS, INC., Santa Clara, CA (US)

(21) Appl. No.: 14/058,837

(22) Filed: Oct. 21, 2013

Related U.S. Application Data
(60) Provisional application No. 61/727,867, filed on Nov. 19, 2012.

(51) Int. Cl. H01L 21/67

(52) U.S. Cl. CPC H01L 21/67011
USPC 137/561 R

(57) ABSTRACT

In some embodiments, a modular chemical delivery system may include a plurality of gas delivery units directly and removably coupled to each other, wherein each gas delivery unit includes a body with a first volume, a plurality of gas sticks disposed in the first volume, wherein each of the plurality of gas sticks is configured to be coupled to at least one gas supply through one or more inlets in the body, a plurality of valves disposed in the first volume, each valve respectively disposed in line with a corresponding one of the at least one gas supply, at least one outlet conduit to deliver at least one process gas to one or more gas delivery zones in a process chamber, and an electrical controller disposed in the first volume and configured to control the plurality of gas sticks and the plurality of valves.

### CROSS-REFERENCE TO RELATED APPLICATIONS

This application claims benefit of U.S. provisional patent application Ser. No. 61/727,867, filed Nov. 19, 2012, which is herein incorporated by reference.

### FIELD

Embodiments of the present invention generally relate to semiconductor substrate processing and more specifically to chemical delivery systems used in semiconductor substrate processing.

### BACKGROUND

Semiconductor manufacturing processes utilize a wide variety of gases that are provided to processing equipment (e.g., cluster tool, process chamber, or the like) via gas delivery systems that are coupled to, or embedded, in the processing equipment.

As semiconductor process recipes become more sophisticated, an increased number of process gases and varying ratios of process gases are required, therefore requiring the need for increasingly complex gas delivery systems. For example, the inventors have observed that in conventional gas delivery systems, for each process gas added to a process recipe, additional hardware (e.g. mass flow controllers, gas pallets, gas conduits, valves, ampoules and the like) needs to be added to the gas delivery system. The additional hardware is typically contained in a large gas box that can take up a lot of space in an electronic device manufacturing facility, or “fab”. Depending on the number of gas pallets and ampoules required for a particular process, only a small portion of the gas box may be used while the rest just takes up space. In addition, large fixed gas boxes may require longer gas lines and do not provide the flexibility to quickly configure the gas delivery system depending on the required hardware for a process.

Thus, the inventors have provided an improved modular chemical delivery system.

### SUMMARY

Apparatus for delivering chemicals to a process chamber are provided herein. In some embodiments, a modular chemical delivery includes a plurality of gas delivery units directly and removably coupled to each other, wherein each gas delivery unit includes a body with a first volume, a plurality of gas sticks disposed in the first volume, wherein each of the plurality of gas sticks is configured to be coupled to at least one gas supply through one or more inlets in the body, a plurality of valves disposed in the first volume, each valve respectively disposed in line with a corresponding one of the at least one gas supply, at least one outlet conduit to deliver at least one process gas to one or more gas delivery zones in a process chamber, and an electrical controller disposed in the first volume and configured to control the plurality of gas sticks and the plurality of valves.

In some embodiments, a substrate processing system may include at least one modular gas box unit having a body with a first volume, a first plurality of gas sticks and a first plurality of valves disposed in the first volume; at least one modular ampoule unit having a body with a second volume, a second plurality of gas sticks, a second plurality of valves, and an ampoule to hold a precursor disposed in the second volume; a controller communicatively coupled to the at least one modular gas box unit and the at least one modular ampoule unit to provide control signals to the at least one modular gas box unit and the at least one modular ampoule unit to produce process gases to the process chamber; and a process chamber configured to receive process gases from the at least one gas box unit and the at least one ampoule unit to process a substrate.

In some embodiments, a modular chemical delivery system to deliver chemicals to a process chamber may include a gas delivery unit configured to be directly and removably coupled to other gas delivery units, wherein the gas delivery unit includes a body with a first volume, a plurality of gas sticks disposed in the first volume, wherein each of the plurality of gas sticks is configured to be coupled to at least one gas supply through one or more inlets in the body, a plurality of valves disposed in the first volume, each valve respectively disposed in line with a corresponding one of the at least one gas supply, at least one outlet conduit to deliver at least one process gas to one or more gas delivery zones in a process chamber, and an electrical controller disposed in the first volume and configured to control the plurality of gas sticks and the plurality of valves.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIGS. 1A-B are schematic depictions of a modular chemical delivery system in accordance with some embodiments of the present invention.

FIGS. 2A-B are schematic depictions of exemplary gas pallet configurations in accordance with some embodiments of the present invention.

FIG. 3 is a schematic depiction of a substrate processing system having a modular chemical delivery system in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Exemplary embodiments of the present invention include modular designs of a chemical delivery system (often referred to in the art as a “gas panel” or “gas box”) to deliver one or more chemicals in gaseous form to various processing chambers. The modular chemical delivery systems described herein may include one or more self-contained gas delivery units. Each self-contained gas delivery unit may be one of a modular gas box unit or a modular ampoule unit. While modular gas box units are designed to deliver both reactive and inert gases to a process chamber, the modular ampoule units may deliver reactants from liquid and solid sources.

Each self-contained modular gas box unit contains a number of mass flow controller (MFC) gas sticks used for gas transmission (one for each gas being used and often referred to in the art as “gas sticks”), and associated pneumatic valves that can be independent to one another (all-individual configuration) or grouped into various configurations (for example, 5-stick configuration or 2-stick/3-stick combined configuration). Along with gas sticks and valves, electrical components and electrical value blocks (EV blocks) necessary to control the gas sticks and open/close the pneumatic valves associated with each gas stick are packaged in a single stand-alone assembly.

Each modular ampoule unit contains one ampoule to hold a liquid or a solid source of a desired precursor. Two gas sticks are packaged with the ampoule. One of these gas sticks is connected to the gas inlet of the ampoule to carry the precursor out (i.e., carrier gas), while the other gas stick is connected to the ampoule gas outlet to deliver gases to dilute the precursor to the desired concentration (i.e., dilute gas). Similar to the modular gas box unit, electrical components and EV blocks necessary to control the gas sticks and open/close the associated pneumatic valves are packaged in the same stand-alone assembly.

As designed, these self-contained gas delivery units (e.g., modular gas box units and modular ampoule units) are self-sufficient modules and can be used either as a stand-alone unit or as part of the entire delivery system with individual modules attached to one another. Any number and configuration of modular gas box units and modular ampoule units may be coupled to provide the desired chemicals to one or more gas delivery zones in one or more process chambers as will be described below.

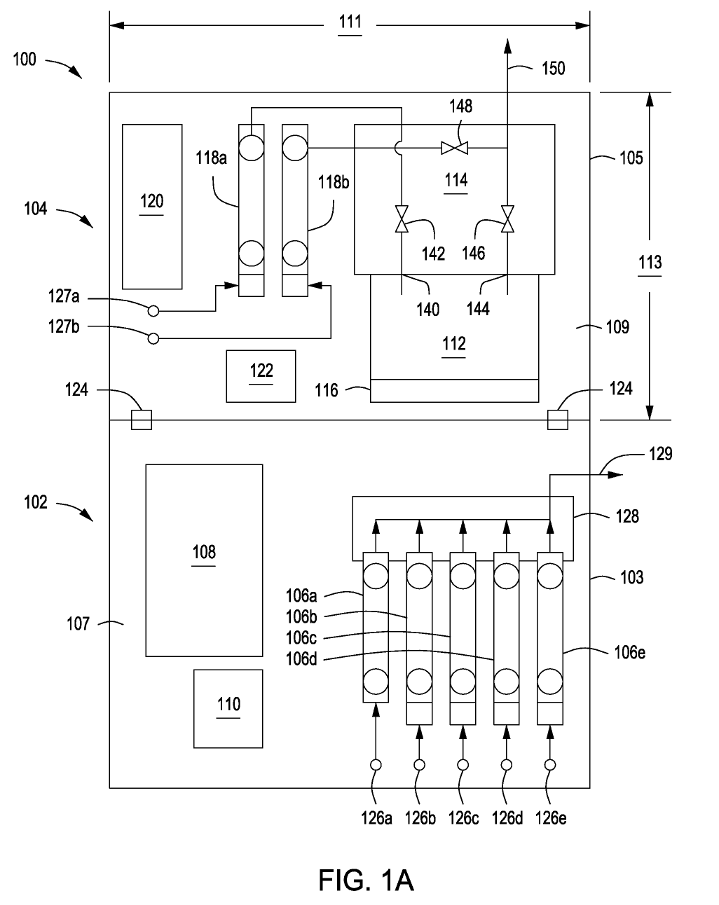

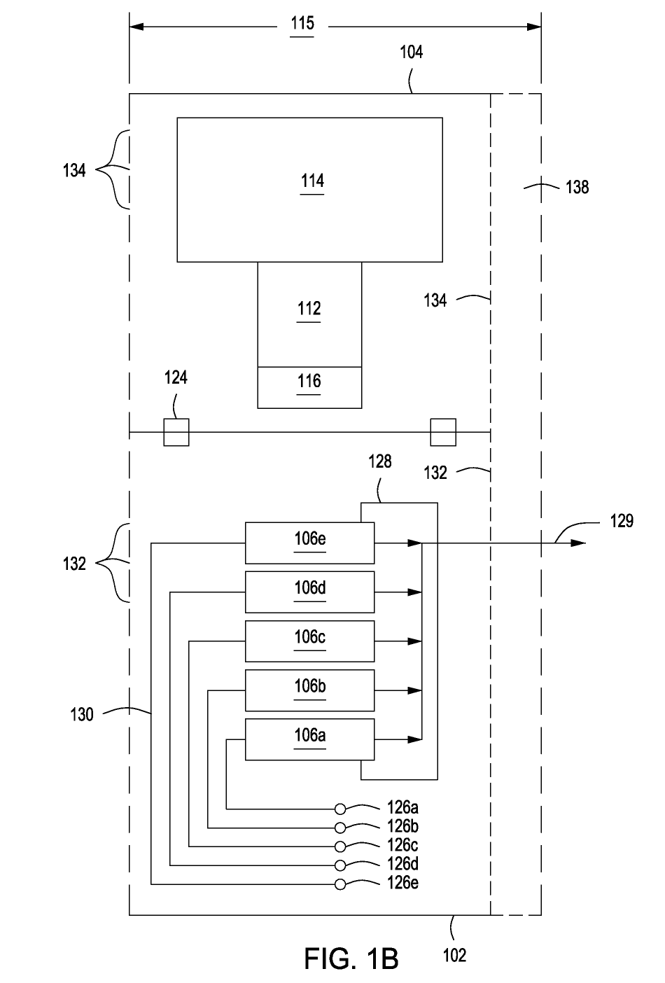

FIGS. 1A-B are schematic front and side view depictions, respectively, of a modular chemical delivery system 100 in accordance with some embodiments of the present invention. The modular chemical delivery system 100 shown in FIGS. 1A and 1B includes two self-contained gas delivery units (a modular gas box unit 102 and a modular ampoule unit 104) for descriptive purposes only. However, as discussed above, embodiments of the present invention may include any number and configuration of gas delivery units 102, 104 coupled together to provide the desired chemicals (e.g., one modular gas box unit only, three modular gas box units, one modular ampoule unit only, five modular gas box units and three modular ampoule units, etc.).

In some embodiments, self-contained gas delivery units 102,104 may be stacked and coupled vertically (as shown in FIGS. 1A-B) or they may be coupled side by side. In some embodiments, the modular gas box units 102 and modular ampoule units 104 are directly and removably coupled to each other, for example, via fasteners 124. In some embodiments, the fasteners 124 may consists of any type of removable fastener which can securely attached the modular units together. For example, the fasteners may consist of bolts, pins, straps, and the like. In addition, in some embodiments fasteners 124 may include interlocking features disposed on the exterior of a body of each of the plurality of self-contained gas delivery units.

In some embodiments, each of plurality of self-contained gas delivery units 102, 104 are substantially similar in size to facilitate stacking and coupling of the units to each other and to minimize space usage in the fab. For example, in some embodiments, the width 111 of each of the self-contained gas delivery units 102, 104 may be about 350 mm to about 400 mm, the height 113 may be about 600 mm to about 650 mm, and the depth 115 may be about 550 mm to about 600 mm. In some embodiments, all the self-contained gas delivery units 102, 104 which comprise the modular chemical delivery system 100 may be enclosed in a single enclosure to confine exhaust gases which may be emitted from each of plurality of self-contained gas delivery units 102, 104.

The modular gas box unit 102 includes a body 103 having an inner volume 107. The modular gas box unit 102 includes a plurality of gas sticks 106a-e disposed in the first volume 107, wherein each of the plurality of gas sticks 106a-e is configured to be coupled to at least one gas supply 126a-e through one or more inlets in the body via gas supply lines 130. In some embodiments, each modular gas box unit 102 may be standardized to include a total of 5 gas sticks 106a-e (4 for reactive gases, and 1 for inert gases). In some embodiments, the number of gas sticks 106a-e included in the modular gas box unit may be about 2 gas sticks (as in the ampoule module without the ampoule) to about 10 gas sticks. In some embodiments, although present in a modular gas box unit, not all gas sticks may be used for a particular process (i.e., some gas sticks may function as unused spare gas sticks). Each of the plurality of gas sticks 106a-e may supply the same or different gases. In addition, gas sticks 106a-e (and/or their associated pneumatic valves) may be controlled to provide their respective gases sequentially, simultaneously, or in combinations thereof.

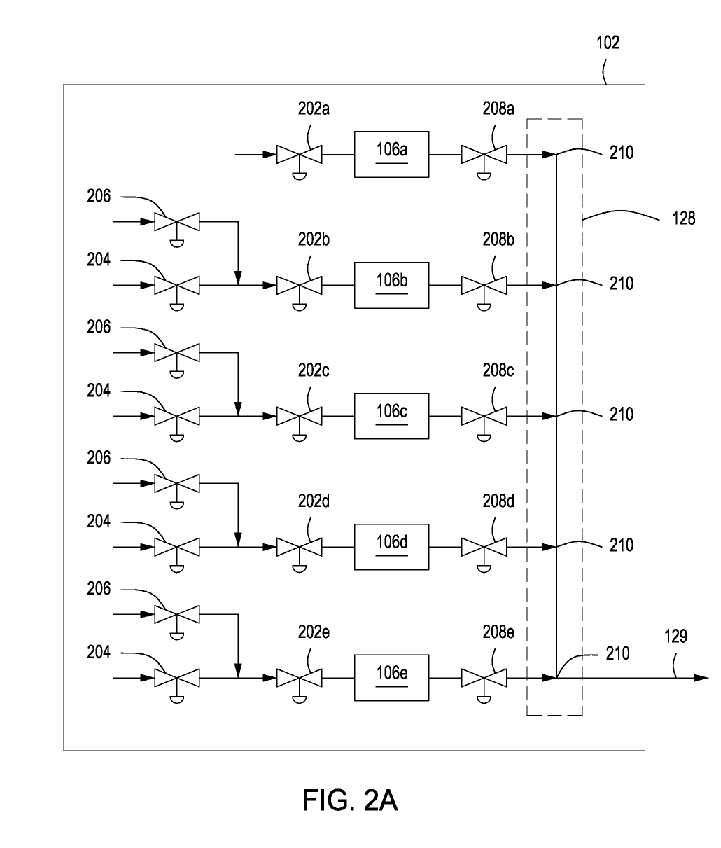

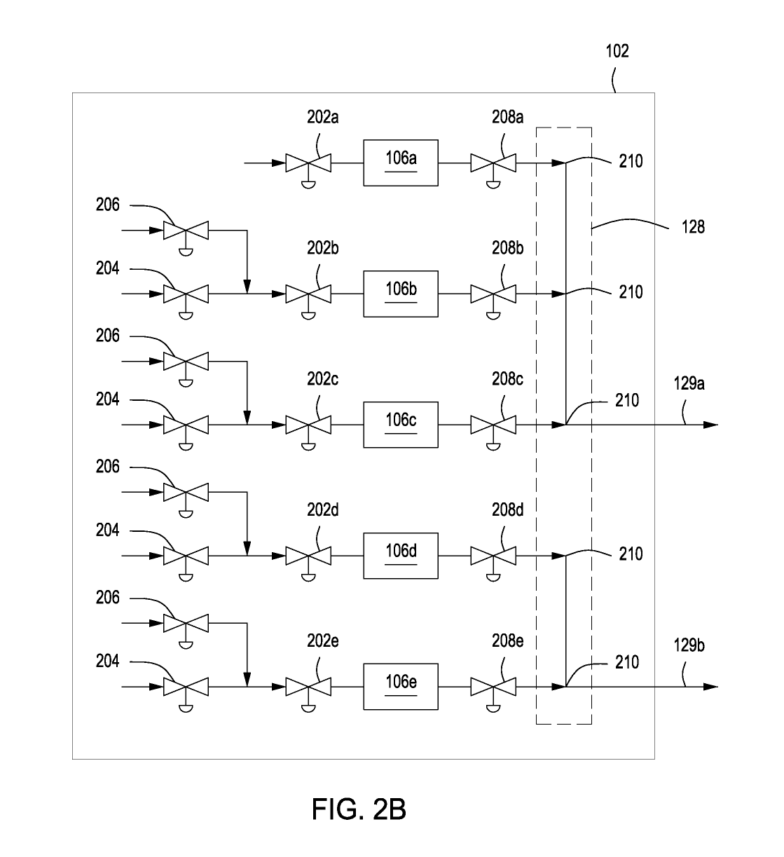

The modular gas box unit 102 includes a plurality of pneumatic valves disposed in the first volume (discussed in detail below with respect to FIGS. 2A-B), each valve respectively disposed in line with a corresponding one of the at least one gas supply. The modular gas box unit 102 includes at least one outlet conduit 129 from a configurable manifold 128, coupled to outlets of gas sticks 106a-e, to deliver at least one process gas to one or more gas delivery zones in a process chamber. In some embodiments, the configurable manifold 128 consisting of a plurality of pneumatic valves and configuration conduits (discussed in detail below with respect to FIGS. 2A-B).

In some embodiments, a modular gas box controller 108 is disposed in the first volume and configured to control the plurality of gas sticks 106a-e and the plurality of valves. Modular gas box controller 108 may include electrical components and Electrical Value blocks (EV blocks) necessary to control the gas sticks and open/close the pneumatic valves associated with each gas stick. In some embodiments, the modular gas box unit 102 may include a communications interface 110, which may communicate modular gas box controller 108, configured to receive control signals (for example, from an external system) to control the plurality of gas sticks and the plurality of valves.

The body 103 of modular gas box unit 102 may include a plurality of air flow holes 132 to facilitate cooling of internal components of the modular gas box unit 102 and to facilitate the purging of gases within the modular gas box unit 102. The exhaust gases may be purged into a common exhaust conduit 138.

The modular ampoule unit 104 includes a body 105 having an inner volume 109. The modular ampoule unit 104 includes an ampoule 112 to hold a liquid or solid precursor and a valve module 114 (referred to in the art as a “hot can”) to heat the precursor. In some embodiments, the modular ampoule unit 104 may include a drip pan 116 to capture the precursor in case the ampoule 112 leaks. In some embodiments, the modular ampoule unit 104 may include a heating/cooling jacket (not shown) wrapped around the amouple to heat/cool the precursor held by ampoule 112.

The modular ampoule unit 104 includes a plurality of gas sticks 118a-b disposed in the volume 109, wherein each of the plurality of gas sticks 118a-b is configured to be coupled to at least one gas supply 127a-b through one or more inlets in the body. In some embodiments, each modular ampoule unit 104 may be standardized to include at least 2 gas sticks 118a-b. In some embodiments, gas stick 118a may be connected an inlet 140 of the ampoule 112 (via valve 142 disposed in valve module 114) to carry the precursor out (i.e., carrier gas). In some embodiments, the precursor may be carried out of ampoule 112 through ampoule outlet 144. The amount of precursor carried out of ampoule 112 may be regulated by valve 146 disposed in valve module 114. In some embodiments, gas stick 118b may be connected to the ampoule gas output line 150 via valve 148 to deliver gases to dilute the precursor to the desired concentration (i.e., dilute gas). In other embodiments, 2 gas sticks may be used to provide dual carrier gas capability, and one gas stick used for the dilute gas. In some embodiments, the number of gas sticks 118a-b included in the modular ampoule unit 104 may be about 2 gas sticks to about 6 gas sticks. In some embodiments, although a plurality of gas sticks may be present in a modular ampoule unit 104, not all gas sticks may be used for a particular process (i.e., some gas sticks may function as unused spare gas sticks). Gas sticks 118a-b (and/or their associated pneumatic valves) may be controlled to provide their respective gases sequentially, simultaneously, or in combinations thereof.

The modular ampoule unit 104 further includes an inlet (not shown) to receive the precursor held by the ampoule 112, an inlet 127a to receive a carrier gas supplied to a first gas stick 118a, an inlet 127b to receive a dilute gas supplied to a second gas stick 118b, and gas output line 150 to flow a gas mixture of the precursor, the carrier gas and the dilute gas from the modular ampoule unit 104. In some embodiments, the modular ampoule unit 104 may include a plurality of pneumatic valves (not shown) disposed in the first volume, each valve respectively disposed in line with a corresponding one of the at least one gas supply.

In some embodiments, a modular ampoule unit controller 120 is disposed in volume 109 and configured to control one or more of the plurality of gas sticks 118a-b, the plurality of valves, ampoule 112, valve module 114 and ampoule heater/cooler jackets (not shown). In some embodiments valve module 114 may include a separate temperature controller (not shown). Modular ampoule unit controller 120 may include electrical components and Electrical Value blocks (EV blocks) necessary to control the gas sticks and open/close the pneumatic valves associated with each gas stick, in addition to control the ampoule 112, valve module 114 and ampoule heater/cooler jackets (not shown). Furthermore, in some embodiments, the modular ampoule unit 104 may include a communications interface 110, which may communicate modular ampoule unit controller 120, configured to receive control signals (for example, from an external system) to control the plurality of gas sticks and the plurality of valves.

The body 105 of modular ampoule unit 104 may include a plurality of air flow holes 134 to facilitate cooling of internal components of the modular ampoule unit 104 and to facilitate the purging of gases within the modular ampoule unit 104. The exhaust gases may be purged into a common exhaust conduit 138.

FIGS. 2A-B are schematic depictions of exemplary gas pallet configurations within modular gas box unit 102 in accordance with some embodiments of the present invention. In exemplary embodiments consistent with FIG. 2A and 2B, a first plurality of pneumatic valves 202a-e are coupled to inputs of gas sticks 106a-e. In some embodiments, a first gas stick 106a and valve 202a may be used to flow an inert gas (e.g., Argon, Nitrogen, or the like). In some embodiments, one or more of gas sticks 106b-106e and valves 202b-e may be used to flow a reactive gas (e.g., SiH₄, H₂, NF₃, WF₆, NH₃, or the like) provided by pneumatic valves 204. In addition, one or more of gas sticks 106b-106e and valves 202b-e may also be used to flow a purge gas (e.g., Argon, Nitrogen, or the like) provided by pneumatic valves 206. In some embodiments, a second plurality of pneumatic valves 208a-e are coupled to outputs of gas sticks 106a-e. In FIG. 2A, one exemplary output configuration included configurable manifold 128 is shown. In FIG. 2A, all configurable output conduits are coupled to each other in a 5-gas stick configuration and provide a single process gas mixture through configurable conduits 210 and to output conduit 129. In FIG. 2B shows a 2-stick/3-stick combined configuration where process gases from gas sticks 106a-c are combined in configurable conduits 210, and output through output conduit 129a. In addition, process gases from gas sticks 106d-e are combined in configurable conduits 210 and output through output conduit 129b. Configurable conduits 210 include “T” shaped conduits, angled conduits, straight conduits, and the like to form the desired combinations. In some embodiments, configurable conduits 210 may be surface mount blocks including gas channels disposed within each block. In addition, although FIGS. 2A and 2B depict two configurations for descriptive purposes, configurable conduits 210 may be arranged in any way to form the desired output configuration. The ends of configurable conduits 210 are configured to connect to each other while forming a seal which substantially limits gas leakage.

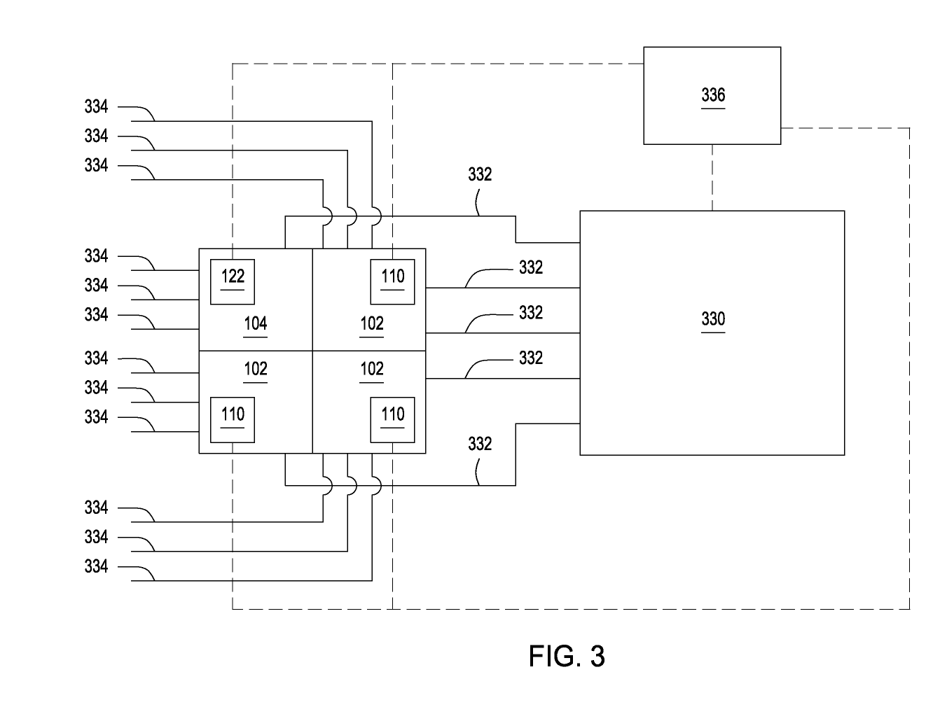

FIG. 3 is a schematic depiction of a substrate processing system in accordance with some embodiments of the present invention. In FIG. 3, a plurality of gas supply conduits 334 provide gases to each of the self-contained gas delivery units (i.e., three modular gas box units 102, and one modular ampoule unit 104). The self-contained gas delivery units 102, 104 provide process gases to one or more gas delivery zones in one or more process chambers 330 via output conduits 332. In FIG. 3, each supply conduit 334 and each output conduit 332 may schematically represent one or more conduits. The amount of process gases supplied by each of the self-contained gas delivery units 102, 104 may be controlled by process tool controller 336 that provides controls signals to self-contained gas delivery units 102, 104 via interfaces 110 and 122. In some embodiments, the controller 336 will include a separate dedicated electrical controller for each self-contained gas delivery unit 102, 104. More specifically, in some embodiments, the controller 336 will include a separate dedicated electrical controller that controls the gas sticks and vales for each self-contained gas delivery unit 102, 104. In other embodiments, each self-contained gas delivery unit 102, 104 may contain an electrical controller that controls the gas sticks and vales for each self-contained gas delivery unit 102, 104.

While the foregoing is directed to embodiments of the present invention, other and further embodiments of the invention may be devised without departing from the basic scope thereof.

1. A modular chemical delivery system to deliver chemicals to a process chamber for semiconductor substrate processing, comprising:
a plurality of gas delivery units directly and removably coupled to each other, wherein each gas delivery unit comprises:
a body enclosing a first volume;
a plurality of gas sticks disposed in the first volume, wherein each of the plurality of gas sticks is configured to be coupled to at least one gas supply through one or more inlets in the body;
a plurality of valves disposed in the first volume, each valve respectively disposed in line with a corresponding one of the at least one gas supply;
at least one outlet conduit to deliver at least one process gas to one or more gas delivery zones in a process chamber; and
a gas delivery unit controller disposed in the first volume and configured to control the plurality of gas sticks and the plurality of valves.

2. The modular chemical delivery system of claim 1, wherein each of plurality of gas delivery units are substantially similar in size.

3. The modular chemical delivery system of claim 1, wherein the plurality of gas delivery units are removably coupled using one or more fasteners.

4. The modular chemical delivery system of claim 1, wherein the plurality of gas delivery units are removably coupled using interlocking features disposed on an exterior of the body of each of the plurality of gas delivery units.

5. The modular chemical delivery system of claim 1, wherein each of plurality of gas delivery units further includes a communications interface configured to receive control signals to control the plurality of gas sticks and the plurality of valves.

6. The modular chemical delivery system of claim 1, wherein the plurality of gas delivery units are disposed in an enclosed container.

7. The modular chemical delivery system of claim 1, wherein at least one of the plurality of gas delivery units is a modular ampoule unit.

8. The modular chemical delivery system of claim 7, wherein the modular ampoule unit includes an ampoule to hold a precursor and a valve module to heat the precursor.

9. The modular chemical delivery system of claim 8, wherein the modular ampoule unit further includes an inlet to receive the precursor held by the ampoule, an inlet to receive a carrier gas supplied to a first gas stick of the plurality of gas sticks, an inlet to receive a dilute gas supplied to a second gas stick of the plurality of gas sticks, and an outlet to flow a gas mixture of the precursor, the carrier gas and the dilute gas from the ampoule.

10. The modular chemical delivery system of claim 1, wherein at least one of the plurality of gas delivery units is a modular gas box unit.

11. The modular chemical delivery system of claim 10, wherein the modular gas box unit includes one gas stick to flow an inert gas, and four gas sticks to flow reactive gases.

12. The modular chemical delivery system of claim 10, wherein the modular gas box unit includes a configurable manifold.

13. The modular chemical delivery system of claim 1, wherein at least of the plurality of gas delivery units is a modular gas box unit, and wherein at least of the plurality of gas delivery units is a modular ampoule unit.

14. A modular chemical delivery system to deliver chemicals to a process chamber for semiconductor substrate processing, comprising:
at least one modular gas box unit having a body with a first volume, a first plurality of gas sticks and a first plurality of valves disposed in the first volume;
at least one modular ampoule unit having a body with a second volume, a second plurality of gas sticks, a second plurality of valves, and an ampoule to hold a precursor disposed in the second volume;
a controller communicatively coupled to the at least one modular gas box unit and the at least one modular ampoule unit to provide control signals to the at least one modular gas box unit and the at least one modular ampoule unit to produce process gases to the process chamber; and
a process chamber configured to receive process gases from the at least one gas box unit and the at least one ampoule unit to process a substrate.

15. The modular chemical delivery system of claim 14, wherein the least one modular gas box unit further includes a first electrical controller configured to control the first plurality of gas sticks and the first plurality of valves, wherein the least one modular ampoule unit further includes a second electrical controller configured to control the second plurality of gas sticks and the second plurality of valves, and wherein the controller is communicatively coupled to the first electrical controller and the second electrical controller.

16. A modular chemical delivery system to deliver chemicals to a process chamber for semiconductor substrate processing, comprising:
a gas delivery unit configured to be directly and removably coupled to other gas delivery units, wherein the gas delivery unit comprises:
a body with a first volume;
a plurality of gas sticks disposed in the first volume, wherein each of the plurality of gas sticks is configured to be coupled to at least one gas supply through one or more inlets in the body;
a plurality of valves disposed in the first volume, each valve respectively disposed in line with a corresponding one of the at least one gas supply; and
at least one outlet conduit to deliver at least one process gas to one or more gas delivery zones in a process chamber.

17. The modular chemical delivery system of claim 16, wherein the gas delivery unit is a modular ampoule unit.

18. The modular chemical delivery system of claim 16, wherein the gas delivery unit is a modular gas box unit.

19. The modular chemical delivery system of claim 16, wherein the gas delivery unit further includes a communications interface configured to receive control signals to control the plurality of gas sticks and the plurality of valves.

20. The modular chemical delivery system of claim 16, wherein the gas delivery unit further includes an electrical controller that controls the plurality of gas sticks and the plurality of valves.
